(19) United States
(12) Patent Application Publication
(10) Pub. No.: US 2026/0297732 A1
(43) Pub. Date: Oct. 1, 2026

(54) METHOD AND APPARATUS FOR PRODUCING METALLIC SILICON

(71) Applicants: HONDA MOTOR CO., LTD., TOKYO (JP); KYUSHU UNIVERSITY, NATIONAL UNIVERSITY CORPORATION, Fukuoka-shi (JP)

(72) Inventors: Toshiaki SUMI, WAKO-SHI (JP); Tadahisa NAKAMURA, WAKO-SHI (JP); Tsuyumi NISHIYAMA, WAKO-SHI (JP); Manabu TANAKA, Fukuoka-shi (JP); Junya MATSUNO, Fukuoka-shi (JP); Takayuki WATANABE, Fukuoka-shi (JP)

(21) Appl. No.: 19/536,421

(22) Filed: Feb. 11, 2026

(30) Foreign Application Priority Data
Mar. 28, 2025 (JP) 2025-056507

(51) Int. Cl. C23C 16/40; H01J 37/32; H05H 1/30; H05H 1/34; H05H 1/42

(52) U.S. Cl. CPC C23C 16/401; H01J 37/32192; H01J 37/32449; H05H 1/30; H05H 1/34; H05H 1/42

(57) ABSTRACT

In a method for producing metallic silicon, a raw material serving as a silica source is supplied to a plasma torch by a carrier gas, and the raw material is reduced by a plasma reaction to recover metallic silicon.

### INCORPORATION BY REFERENCE

The present application claims priority under 35 U.S.C. § 119 to Japanese Patent Application No. 2025-056507 filed on Mar. 28, 2025. The content of the application is incorporated herein by reference in its entirety.

### BACKGROUND OF THE INVENTION

### Field of the Invention

The present invention relates to a method and an apparatus for producing metallic silicon.

### Description of the Related Art

In recent years, efforts to significantly reduce the generation of waste through the prevention of generation, reduction, recycling, and reuse of wastes have intensified. To achieve this, research and development on the recycling of silicon has been conducted.

Japanese Patent Laid-Open No. 2020-090429 discloses a technique for producing bio-derived metallic silicon by calcining chaff, rice straw, and the like as the silica source to produce silica ash, mixing the silica ash and a required amount of carbon, and heating the raw material from the inside thereof under microwaves.

However, with respect to the technique relating to the recycling of silicon, the technique of Japanese Patent Laid-Open No. 2020-090429 has problems in that a carbon source is required to obtain metallic silicon, the carbon source generates CO2, and CO2 is required to be treated considering the environment, and in that the silica ash is required to be processed into a bulky or pellet form by the addition of a linking agent, and the like.

An object of the present application to solve the above problems is to achieve the continuous production of metallic silicon while reducing the electric power consumed, without requiring the processing of the silica source into a bulky or pellet form and generating CO2. Then, the present application contributes to a significant reduction of the generation of waste.

### SUMMARY OF THE INVENTION

An aspect of the present invention is a method for producing metallic silicon, including supplying a raw material serving as a silica source to a plasma torch by a carrier gas, and reducing the raw material by a plasma reaction to recover metallic silicon.

According to an aspect of the present invention, metallic silicon can be continuously produced while reducing the electric power consumed, without requiring the processing of the silica source into a bulky or pellet form and generating CO2.

### BRIEF DESCRIPTION OF THE DRAWINGS

FIG. 1 is a diagram showing the production apparatus of Embodiment 1;

FIG. 2 is a diagram showing the conditions of the demonstration experiment;

FIGS. 3A and 3B are diagrams showing Experimental Result 1;

FIG. 4 is a diagram showing the production apparatus of Embodiment 2;

FIG. 5 is a diagram showing the conditions of the demonstration experiment;

FIG. 6 is a diagram showing Experimental Result 2; and

FIG. 7 is a diagram showing Experimental Result 3.

### DETAILED DESCRIPTION OF THE INVENTION

### Embodiment 1

### (Configuration of Production Apparatus)

Hereinafter, Embodiment 1 of the present invention will be described with reference to the drawings.

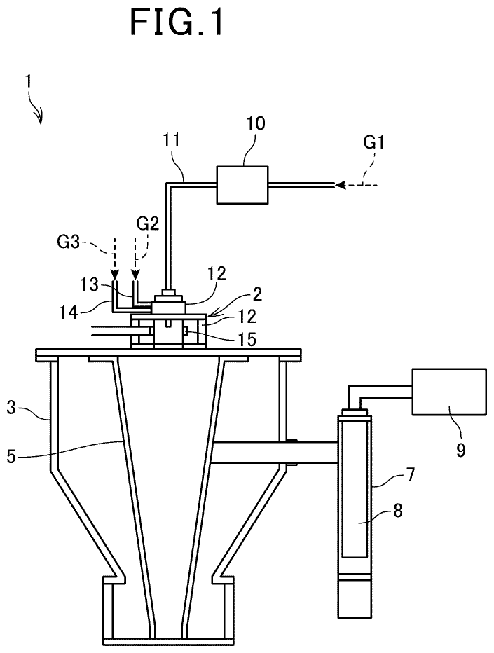

FIG. 1 is a diagram showing a production apparatus 1 of metallic silicon. Metallic silicon is simple substance Si.

The production apparatus 1 of metallic silicon includes a plasma torch 2.

In the plasma torch 2, an outer chamber 3 is continuously formed. The outer chamber 3 accommodates an inner chamber 5, and a filter chamber 7 is connected to the inner chamber 5. The filter chamber 7 accommodates a filter 8. Further, a suction pump 9 is connected to the filter chamber 7.

A raw material vessel 10 is connected to the plasma torch 2. A bio-derived powder raw material as the raw material is stored in the raw material vessel 10.

The bio-derived powder raw material is obtained by finely pulverizing ash or charcoal of, for example, chaff and straw of rice and wheat, bamboo leaves, and corn leaves and canes, as the raw material serving as a silica source. For example, the ash of gramineous plants that contain a large amount of silica is preferable as the bio-derived powder raw material. The raw material may be obtained by pulverizing a low-grade silica source such as quartz glass and silica sand.

The plasma torch 2 includes an introduction pipe 12 on the upstream side. To the introduction pipe 12, a carrier gas pipe 11, a sheath gas pipe 13, and an inner gas pipe 14 are connected. The introduction pipe 12 is, for example, a triple pipe.

To the raw material vessel 10, a carrier gas that is an inert gas such as Ar is supplied through the carrier gas pipe 11, as shown by an arrow G1. This carrier gas carries the raw material in the raw material vessel 10 through the introduction pipe 12 to the plasma torch 2.

The carrier gas may be helium (He), nitrogen (N2), hydrogen (H2), or the like.

To the introduction pipe 12 of the plasma torch 2, a sheath gas that is a mixture of Ar and hydrogen is supplied through the sheath gas pipe 13, as shown by an arrow G2.

The sheath gas protects the plasma torch 2 from heat.

To the introduction pipe 12 of the plasma torch 2, an inner gas that is an inert gas such as Ar is supplied through the inner gas pipe 14, as shown by an arrow G3.

The inner gas may be helium (He), nitrogen (N2), hydrogen (H2), or the like. The component of the inner gas is largely converted to plasma.

In the inside of the introduction pipe 12, for example, the sheath gas is made to flow through the outer periphery of the carrier gas, and the inner gas is made to flow through the outer periphery of the sheath gas.

The plasma torch 2 includes a coil accommodation section 16 and a coil 15 that is accommodated in the coil accommodation section 16 on the downstream side of the introduction pipe 12. To the coil 15, plasma power of a predetermined wattage is applied, and an electric current is made to flow at a predetermined frequency (e.g., 4 MHz), so that the plasma reaction occurs particularly in the coil accommodation section 16 of the plasma torch 2. The coil 15 is connected to an apparatus for applying an AC power supply (not shown).

### (Production Method)

The sheath gas and the inner gas are supplied to the plasma torch 2, and the raw material in the raw material vessel 10 is carried to the plasma torch 2 by the carrier gas. In the plasma torch 2, the raw material is reduced by the plasma reaction to produce metallic silicon. That is, in the plasma torch 2, the oxide of silicon such as silica is reduced to produce simple substance Si.

Since the raw material is treated under a super-high temperature in the plasma torch 2, the reaction time for obtaining metallic silicon is short, and metallic silicon can be produced in a short time, so that the electric power consumed can be reduced.

In addition, since the plasma reaction occurs in the hydrogen gas, there is no need to separately add a carbon source as in the conventional method, and no CO2 is generated, so that the treatment considering the environment is not required. The plasma reaction is not limited to the plasma reaction in hydrogen gas. For example, the present production method is also applicable to the plasma reaction in carbon gas or fluorine gas.

The raw material is a bio-derived powder raw material.

According to the present invention, the raw material may be powder and is not required to be processed into a bulky or pellet form by the addition of a linking agent, as in the conventional method. In addition, powder supply can be continuously treated and is applicable to line production even when the facility size is small.

From the plasma torch 2, the main stream that is the flow of gas containing a reactant is discharged into the inner chamber 5. Metallic silicon is recovered in the inner chamber 5, and a part of metallic silicon is recovered in the filter chamber 7. Since the raw material serving as the silica source is evaporated once in the plasma torch 2, the metallic silicon produced has a significantly fine particle size. Thus, a subsequent step for pulverizing metallic silicon is unnecessary.

To enhance the purity of metallic silicon, for example, solution treatment for removing a natural oxide film on the surface of metallic silicon (HF treatment) may be carried out.

Alternatively, the Siemens process in which trichlorosilane (SiHCl3) obtained from metallic silicon is used as the raw material, reacted with hydrogen gas at high temperatures, and thermally decomposed to precipitate metallic silicon in high purity may be carried out.

### (Experimental Result 1)

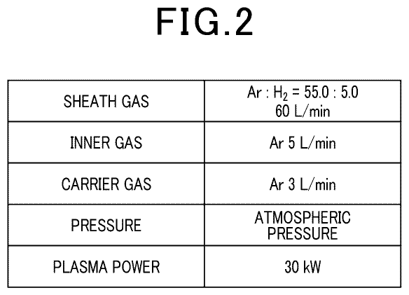

With reference to FIG. 2, rice husk ash was used as the raw material, and as for the sheath gas, the proportion of Ar:hydrogen was set to 55.0:5.0, and the flow rate was set to 60 L/min. The flow rate of Ar serving as the inner gas was set to 5 L/min, and the flow rate of Ar serving as the carrier gas was set to 3 L/min. The plasma power was set to 30 kW, and a demonstration experiment of the metallic silicon production was carried out under atmospheric pressure.

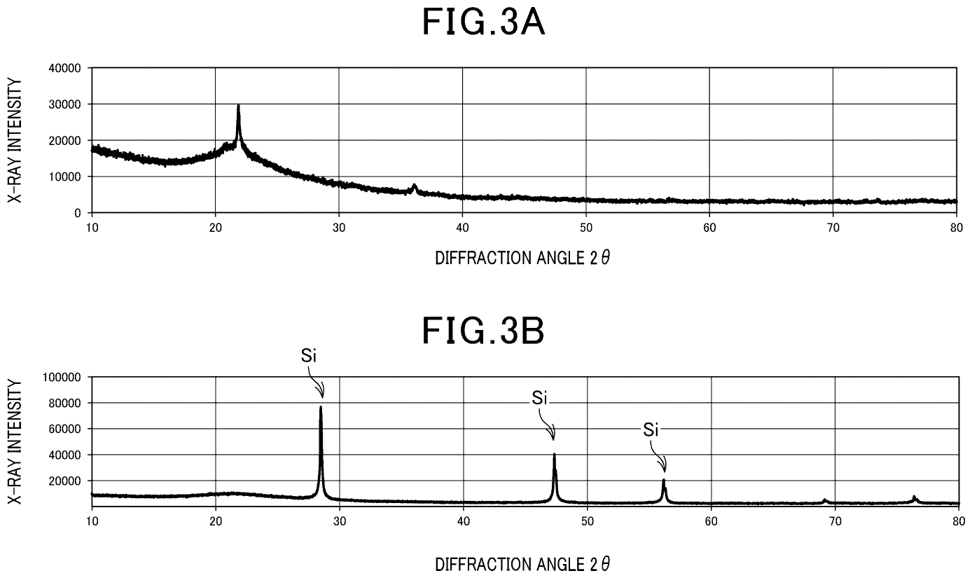

FIGS. 3A and 3B show Experimental Result 1. Experimental Result 1 is the results of X-ray diffraction (XRD). The vertical axis indicates the X-ray intensity (the unit is cps) and the horizontal axis indicates the diffraction angle 2θ (the unit is deg).

FIG. 3A indicates the rice husk ash before the plasma treatment and FIG. 3B indicates the rice husk ash after the plasma treatment.

In FIG. 3B after the plasma treatment, peaks corresponding to the databases of metallic silicon are found at 3 points. The diffraction angles 2θ of three peaks corresponding to metallic silicon are 28.4 corresponding to the case where the Miller index is (111), 47.3 corresponding to the case where the Miller index is (220), and 56.1 corresponding to the case where the Miller index is (311). In (A) before plasma treatment, the peaks are not found, and it is found that metallic silicon is produced in high purity in (B) after the plasma treatment.

The present inventors have carried out various demonstration experiments, and have obtained the following findings.

The plasma power applied to the plasma torch 2 is, for example, in a range of 3 kW or more and 300 kW or less, and preferably in a range of 15 kW or more and 50 kW or less.

When the plasma power is low, the powder containing silica, which is the raw material, cannot be sufficiently heated. When the plasma power is too high, the stable plasma generation by the present plasma generation method may be obstructed, and contamination with impurities and the like may occur. The pressure in the plasma generation apparatus is, for example, in a range of 10 kPa or more and atmospheric pressure or less.

The flow rate of the carrier gas that carries the raw material serving as the silica source to the plasma torch 2 is desirably 1 L/min or more and 5 L/min or less. When the flow rate of the carrier gas is small, the raw material powder is not sufficiently introduced into the plasma. When the carrier gas flow rate is too large, the residence time in the plasma is short, resulting in insufficient treatment.

The supply rate of the raw material powder serving as the silica source is preferably 50 mg/min or more and 3,000 mg/min or less, and more preferably 200 mg/min or more and 800 mg/min or less. When the supply rate is too high, the heat of the plasma is taken, and the temperature in the plasma reaction region may be reduced. When the supply rate is too low, the raw material powder may be oxidized by being affected by an oxygen source that is incorporated into the production apparatus 1 in a trace amount. When the supply rate is too high, the reduction rate by the reducing radical may be reduced.

The flow rate of the sheath gas supplied to the plasma torch 2 is desirably 40 L/min or more and 100 L/min or less. In the sheath gas, hydrogen molecules serving as the source of hydrogen atoms having strong reducing power are introduced as the mixed gas with an inert gas such as argon.

The proportion of the flow rate of the hydrogen molecules as the mixed gas before being introduced into the plasma torch 2 is preferably 10% or more and 100% or less, and still more preferably 20% or more and 50% or less.

When the proportion of the flow rate of the hydrogen molecules is low, the supply of hydrogen atoms used for the reduction is insufficient, and when the proportion of the flow rate of the hydrogen molecules is high, the plasma volume that is the volume of the region in the plasma torch 2 where the plasma reaction occurs is small, and the region of the plasma reaction may be narrowed.

Examples of the flow rate of the inner gas supplied to the plasma torch 2 include 1 L/min or more and 5 L/min or less.

The raw material serving as the silica source is a bio-derived powder raw material. Since a smaller particle size allows the reduction reaction to progress more quickly, the particle size of the powder raw material is preferably as small as possible. However, when the particle size of the raw material is too small (e.g., less than 10 μm), the supply of the raw material is difficult. In addition, when the particle size of the raw material is too large (e.g., more than 100 μm), the supply of the raw material is difficult. From the viewpoint of the supply of the raw material and the rate of the reduction reaction, the particle size of the raw material is preferably 10 μm or more and 100 μm or less.

### Embodiment 2

### (Configuration of Production Apparatus)

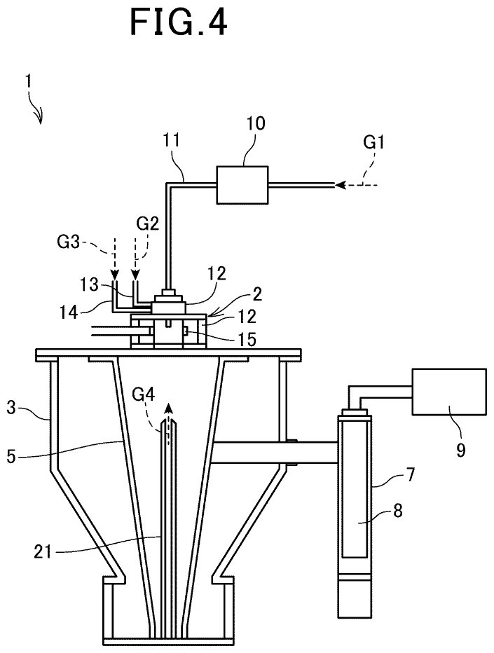

FIG. 4 is a diagram showing Embodiment 2. In FIG. 4, the same parts as in FIG. 1 are designated by the same reference signs, and the descriptions thereof are omitted.

In Embodiment 2, a supply pipe 21 for supplying a quenching gas shown by an arrow G4 is arranged inside the inner chamber 5 from the lower part to the upper part of the inner chamber 5. The quenching gas is methane (CH4).

In the supply pipe 21, an inlet is opened at the lower end part, and an outlet is opened at the upper end part. The upper end part may be referred to as the tip part of the supply pipe 21. By making CH4 collide with the ion or plasma generated in the plasma torch 2, the ion or plasma loses energy, so that gas amplification can be prevented.

### Experimental Result 2

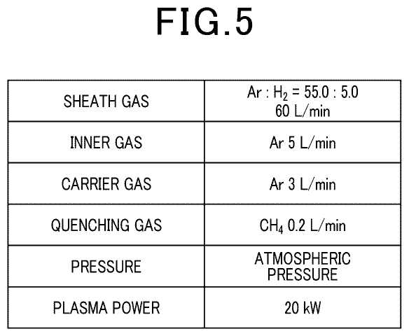

With reference to FIG. 5, rice husk ash was used as the raw material, and as for the sheath gas, the proportion of Ar:hydrogen was set to 55.0:5.0, and the flow rate was set to 60 L/min. The flow rate of Ar serving as the inner gas was set to 5 L/min, and the flow rate of Ar serving as the carrier gas was set to 3 L/min. The plasma power was set to 20 kW, and a demonstration experiment of the metallic silicon production was carried out under atmospheric pressure. The flow rate of CH4 serving as the quenching gas was set to 0.2 L/min.

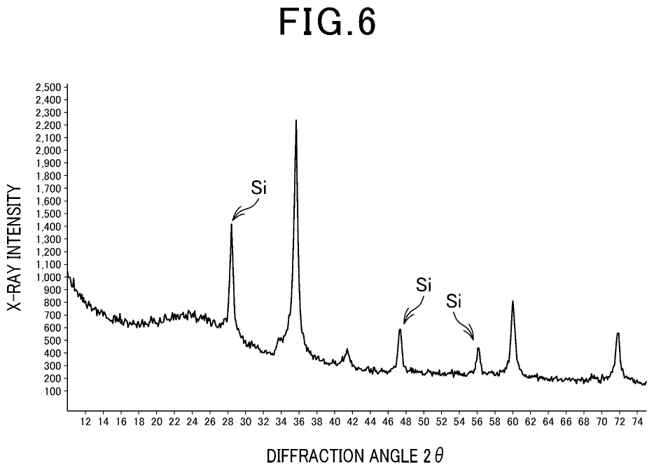

FIG. 6 shows Experimental Result 2.

FIG. 6 shows the rice husk ash after the plasma treatment.

As shown in FIG. 6, the peaks of metallic silicon are found at three points, that is at diffraction angles 2θ of 28.4, 47.3, and 56.1 after the plasma treatment.

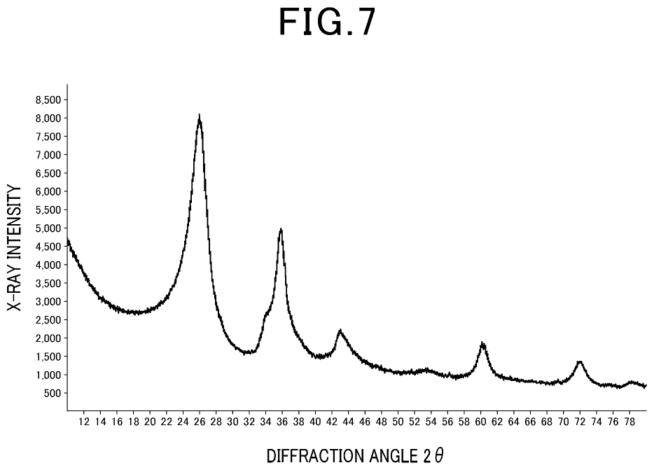

FIG. 7 shows Experimental Result 3.

In this case, the flow rate of the quenching gas was changed from the conditions of Experimental Result 2 and set to 2.0 L/min. As shown in FIG. 7, no peaks of metallic silicon are found in Experimental Result 3, as compared with Experimental Result 2.

Thus, when the flow rate of CH4 serving as the quenching gas is too high, metallic silicon is hardly produced.

The present inventors have carried out various demonstration experiments, and have obtained the following findings.

The temperature in the plasma is about 7,000° C. to 20,000° C. Silica is vaporized as the reduced Si, SiO, or further hydrogenated SiH in the plasma. The passage flow containing these vaporized components is cooled, and nuclei of Si and SiO are produced at about 2,000° C. to 2,500° C. Si and SiO after nucleation are further rapidly cooled to about room temperature. In the rapid cooling process, Si fine powder, SiO fine powder, and SiO2 fine powder are formed.

By introducing a quenching gas containing a carbon component, such as methane gas, into the gas in the cooling process at 1,500° C. to 2,000° C., the Si fine powder and the SiO fine powder can be prevented from reoxidized by water vapor and the like.

The flow rate of the quenching gas is preferably 0.1 L/min or more and 0.5 L/min or less.

When the flow rate of the quenching gas is low, the prevention of reoxidization is insufficient, so that the yield of metallic silicon is not increased. A high flow rate of the quenching gas leads to the production of impurities such as silicon carbide SiC.

With respect to the introduction position of the quenching gas, the quenching gas is desirably supplied at a position 100 mm or more and 200 mm or less apart from the lower end of the plasma torch 2.

When the introduction position is too far from the lower end of the plasma torch 2, the temperature of the quenching gas to be introduced is reduced and methane is not sufficiently decomposed, so that reoxidization cannot be prevented. When the introduction position is too close to the lower end of the plasma torch 2, CH4 is introduced in a high temperature region of 3.000° C. or more, which leads to the production of impurities such as silicon carbide SiC.

The supply pipe 21 is arranged such that the side stream containing the quenching gas is discharged at an angle of 180° to the main stream discharged from the plasma torch 2 to the inner chamber 5. With such a configuration, the ion or plasma generated in the plasma torch 2 can be rapidly cooled, whereas the main stream collides with the side stream at an angle of 180°, which makes the airflow complicated, and the yield of metallic silicon may be reduced.

More specifically, when the airflow is complicated, a circulation flow is instantaneously generated, rapid cooling of the ion or plasma generated in the plasma torch 2 is not sufficiently carried out, and metallic silicon is heated again and reoxidized, which may result in the reduction of the yield of metallic silicon.

Thus, the angle between the main stream and the side stream is not particularly limited to 180°, and may be 45° or more and less than 180°. For example, when the angle between the main stream and the side stream is 90°, the supply pipe 21 is arranged orthogonal to the main stream discharged from the plasma torch 2. For example, when the angle between the main stream and the side stream is 45°, the supply pipe 21 is arranged in the inner chamber 5 from the upper part to the lower part at an angle of 45° to the main stream discharged from the plasma torch 2.

The position at which the side stream containing the quenching gas is supplied has a strong correlation with the temperature of the main stream when the main stream is rapidly cooled to stop the reaction in the main stream. The temperature of the main stream when the main stream is rapidly cooled is desirably about 1,550° C. or less at which solid particles corresponding to metallic silicon are formed. Thus, the tip part of the supply pipe 21 corresponding to the position where the quenching gas is supplied to the main stream is preferably arranged at a position where the temperature of the main stream is 1,200° C. or more and 1,600° C. or less.

### OTHER EMBODIMENTS

Each of the aforementioned embodiments shows merely an aspect and is arbitrarily modifiable and applicable.

### (Configuration Supported by Embodiments)

The above embodiments support the following configurations.

### (Configuration 1)

A method for producing metallic silicon, comprising supplying a raw material serving as a silica source to a plasma torch by a carrier gas, and reducing the raw material by a plasma reaction to recover metallic silicon.

According to the configuration 1, the raw material can be continuously supplied by the carrier gas, and metallic silicon can be obtained by the plasma reaction with a short reaction time. Thus, metallic silicon can be continuously produced while reducing the electric power consumed, without requiring the processing of the silica source into a bulky or pellet form and generating CO2.

### (Configuration 2)

The method for producing metallic silicon according to the configuration 1, wherein the raw material is a bio-derived powder raw material, and a particle size of the raw material is 10 μm or more and 100 μm or less.

According to the configuration 2, metallic silicon can be obtained from the bio-derived raw material that is supposed to be waste, which enables recycling of silicon. In addition, according to the configuration 2, the powder raw material is easily supplied by the carrier gas.

### (Configuration 3)

The method for producing metallic silicon according to the configuration 1 or 2, comprising supplying a sheath gas to the plasma torch, wherein the sheath gas is introduced as a mixed gas of hydrogen molecules serving as a source of hydrogen atoms having strong reducing power and an inert gas, and a proportion of a flow rate of the hydrogen molecules before being introduced into the plasma torch is 10% or more and 100% or less in the mixed gas.

According to the configuration 3, hydrogen is used as the reducing agent, so that no CO2 is generated in the plasma reaction.

### (Configuration 4)

The method for producing metallic silicon according to the configuration 3, wherein a flow rate of the sheath gas is 40 L/min or more and 100 L/min or less.

According to the configuration 4, the efficiency of the reduction of the raw material by the plasma reaction is improved.

### (Configuration 5)

The method for producing metallic silicon according to the configuration 3 or 4, wherein the proportion of the flow rate of the hydrogen molecules is 20% or more and 50% or less in the mixed gas.

According to the configuration 5, the supply of hydrogen atoms to be used in the reduction is sufficient, and the volume where the plasma reaction occurs can be made sufficiently large, so that the region of the plasma reaction can be ensured.

### (Configuration 6)

The method for producing metallic silicon according to any one of the configurations 1 to 5, wherein a flow rate of the carrier gas is 1 L/min or more and 5 L/min or less.

According to the configuration 6, the efficiency of the reduction of the raw material by the plasma reaction is improved.

### (Configuration 7)

The method for producing metallic silicon according to any one of the configurations 1 to 5, comprising supplying an inner gas to the plasma torch, wherein a flow rate of the inner gas is 1 L/min or more and 5 L/min or less.

According to the configuration 7, the efficiency of the reduction of the raw material by the plasma reaction is improved.

### (Configuration 8)

The method for producing metallic silicon according to any one of the configurations 1 to 7, comprising supplying a quenching gas downstream of the plasma torch, wherein a flow rate of the quenching gas is 0.1 L/min or more and 0.5 L/min or less.

According to the configuration 8, the reoxidization of the metallic silicon or Si compound reduced by the plasma reaction can be prevented.

### (Configuration 9)

The method for producing metallic silicon according to any one of the configurations 1 to 8, wherein plasma power applied to the plasma torch is 3 kW or more and 300 kW or less.

According to the configuration 9, the raw material can be sufficiently heated and the plasma is stably generated.

### (Configuration 10)

The method for producing metallic silicon according to any one of the configurations 1 to 9, an inner chamber is continuous with the plasma torch and a filter chamber is connected to the inner chamber, and the method for producing metallic silicon comprises recovering the metallic silicon from each of the inner chamber and the filter chamber.

According to the configuration 10, metallic silicon is easily recovered.

### (Configuration 11)

The method for producing metallic silicon according to the configuration 10, comprising supplying a quenching gas downstream of the plasma torch, wherein a flow rate of the quenching gas is 0.1 L/min or more and 0.5 L/min or less, the inner chamber includes a supply pipe, and the quenching gas is supplied from the supply pipe.

According to the configuration 11, by making quenching gas collide with the ion or plasma generated in the plasma torch, the ion or plasma loses energy, so that gas amplification can be prevented.

### (Configuration 12)

An apparatus for producing metallic silicon, comprising a plasma torch, an outer chamber being continuous with the plasma torch, an inner chamber accommodated in the outer chamber, and a filter chamber connected to the inner chamber, wherein a raw material serving as a silica source is supplied to the plasma torch by a carrier gas, the raw material is reduced by a plasma reaction to produce metallic silicon, and the metallic silicon is recovered from each of the inner chamber and the filter chamber.

According to the configuration 12, the raw material can be continuously supplied by the carrier gas, and metallic silicon can be obtained by the plasma reaction with a short reaction time. Thus, metallic silicon can be continuously produced while reducing the electric power consumed, without requiring the processing of the silica source into a bulky or pellet form and generating CO2.

### REFERENCE SIGNS LIST

1 . . . apparatus for producing metallic silicon, 2 . . . plasma torch, 3 . . . outer chamber, 5 . . . inner chamber, 7 . . . filter chamber, 8 . . . filter, 9 . . . suction pump, 10 . . . raw material vessel, 11 . . . carrier gas pipe, 12 . . . introduction pipe, 13 . . . sheath gas pipe, 14 . . . inner gas pipe, 15 . . . coil, 16 . . . coil accommodation section, 21 . . . supply pipe.

1. A method for producing metallic silicon, comprising supplying a raw material serving as a silica source to a plasma torch by a carrier gas, and reducing the raw material by a plasma reaction to recover metallic silicon.

2. The method for producing metallic silicon according to claim 1, wherein
the raw material is a bio-derived powder raw material, and
a particle size of the raw material is 10 μm or more and 100 μm or less.

3. The method for producing metallic silicon according to claim 2, comprising supplying a sheath gas to the plasma torch, wherein
the sheath gas is introduced as a mixed gas of hydrogen molecules serving as a source of hydrogen atoms having strong reducing power and an inert gas, and
a proportion of a flow rate of the hydrogen molecules before being introduced into the plasma torch is 10% or more and 100% or less in the mixed gas.

4. The method for producing metallic silicon according to claim 3, wherein a flow rate of the sheath gas is 40 L/min or more and 100 L/min or less.

5. The method for producing metallic silicon according to claim 3, wherein the proportion of the flow rate of the hydrogen molecules is 20% or more and 50% or less in the mixed gas.

6. The method for producing metallic silicon according to claim 1, wherein a flow rate of the carrier gas is 1 L/min or more and 5 L/min or less.

7. The method for producing metallic silicon according to claim 1, comprising supplying an inner gas to the plasma torch, wherein
a flow rate of the inner gas is 1 L/min or more and 5 L/min or less.

8. The method for producing metallic silicon according to claim 1, comprising supplying a quenching gas downstream of the plasma torch, wherein
a flow rate of the quenching gas is 0.1 L/min or more and 0.5 L/min or less.

9. The method for producing metallic silicon according to claim 1, wherein plasma power applied to the plasma torch is 3 kW or more and 300 kW or less.

10. The method for producing metallic silicon according to claim 1, wherein
an inner chamber is continuous with the plasma torch and a filter chamber is connected to the inner chamber, and
the method for producing metallic silicon comprises recovering the metallic silicon from each of the inner chamber and the filter chamber.

11. The method for producing metallic silicon according to claim 10, comprising supplying a quenching gas downstream of the plasma torch, wherein
a flow rate of the quenching gas is 0.1 L/min or more and 0.5 L/min or less,
the inner chamber includes a supply pipe, and
the quenching gas is supplied from the supply pipe.

12. An apparatus for producing metallic silicon, comprising a plasma torch, an outer chamber being continuous with the plasma torch, an inner chamber accommodated in the outer chamber, and a filter chamber connected to the inner chamber, wherein
a raw material serving as a silica source is supplied to the plasma torch by a carrier gas, the raw material is reduced by a plasma reaction to produce metallic silicon, and the metallic silicon is recovered from each of the inner chamber and the filter chamber.
